(19) United States
(12) Patent Application Publication
(10) Pub. No.: US 2008/0135825 A1
(43) Pub. Date: Jun. 12, 2008

(54) PHASE-CHANGE MEMORY DEVICE AND METHOD OF FABRICATING THE SAME

(75) Inventors: Seung Yun Lee, Daejeon (KR); Sung Min Yoon, Daejeon (KR); Nam-Yeal Lee, Daejeon (KR); Young Sam Park, Daejeon (KR); Byoung Gon Yu, Daejeon (KR)

Correspondence Address: LAHIVE & COCKFIELD, LLP, ONE POST OFFICE SQUARE, BOSTON, MA, 02109-2127, US

(73) Assignee: Electronics and Telecommunications Research Institute, Daejeon (KR)

(21) Appl. No.: 11/936,503

(22) Filed: Nov. 7, 2007

(30) Foreign Application Priority Data
Dec. 7, 2006 (KR) 10-2006-0124118

(51) Int. Cl. H01L 47/00; H01L 21/8239

(52) U.S. Cl. 257/4; 438/238; 257/E21.645; 257/E45.002

(57) ABSTRACT

Provided are a phase-change memory device and a method of fabricating the same. The phase-change memory device includes a transistor disposed on a semiconductor substrate and including a gate electrode and first and second impurity regions disposed on both sides of the gate electrode; a bit line electrically connected to the first impurity region; and a phase-change resistor electrically connected to the second impurity region, wherein the phase-change resistor includes: a lower electrode formed of a doped SiGe layer; a phase-change layer contacting the lower electrode; and an upper electrode connected to the phase-change layer. The lower electrode is formed of the doped SiGe layer, which has a high resistivity and a low thermal conductivity, thereby reducing a reset current and the power consumption of the entire phase-change memory device.

### CROSS-REFERENCE TO RELATED PATENT APPLICATION

This application claims the benefit of Korean Patent Application No. 10-2006-0124118, filed on Dec. 7, 2006, in the Korean Intellectual Property Office, the disclosure of which is incorporated herein in its entirety by reference.

### BACKGROUND OF THE INVENTION

1. Field of the Invention

The present invention relates to a semiconductor device and a method of fabricating the same, and more particularly, to a phase-change memory device, which can reduce the magnitude of a reset current, and a method of fabricating the same.

This work was supported by the IT R&D program of MIC/IITA. [2005-S-072-02, Technology of a nano scale phase change data storage]

2. Description of the Related Art

Phase-change memory devices operate based on the principle that a crystalline phase of a phase-change material and a corresponding electrical resistance are changed in response to electrical input pulse. When comparing such phase-change memory devices with dynamic random access memory (DRAM) devices and static random access memory (SRAM) devices, the phase-change memory devices can retain data even if power supply is interrupted. When comparing the phase-change memory devices with ferroelectric random access memory (FeRAM) devices and magnetic random access memory (MRAM) devices, the phase-change memory devices can be reliably fabricated using a relatively simple process.

When an electrical input, such as a current or a voltage, is applied to the phase-change material, the phase-change material is reversibly switched between an amorphous phase and a crystalline phase by heat generated by the electrical input. The electrical resistance of the amorphous phase-change material is at least one hundred times as high as that of the crystalline phase-change material. In the phase-change memory devices, the transition from an amorphous phase to a crystalline phase is called “set,” and the transition from a crystalline phase to an amorphous phase is called “reset.” The amount of heat required for reset is larger than that of heat required for set.

A unit cell of the phase-change memory devices may includes a single phase-change resistor and a single transistor. When a threshold voltage or higher is applied to a word line, the transistor is turned on, so that the phase-change resistor is electrically connected to a bit line. Thus, a current is supplied to the phase-change resistor from the bit line, so that the phase of the phase-change resistor can be changed. Voltage lower than threshold voltage is applied to the device and data can be read by resistance difference.

FIG. 1 is a cross-sectional view of a conventional phase-change memory device.

Referring to FIG. 1, a phase-change layer 13 constituting a resistor is connected to lower and upper electrodes 12 and 14, which are connected to lower and upper interconnection lines 11 and 15, respectively.

In general, the lower electrode 12, formed of a material with a high resistivity is allowed to generate a large amount of Joule heat, thereby causing the phase change of the phase-change layer 13 that contacts the lower electrode 12. In this case, as the resistivity of the lower electrode 12 increases and its thermal conductivity decreases, the phase change of the phase-change layer 13 is facilitated. The lower electrode 12 is conventionally formed of TiN, TiSiC, or TiAlN, which has a higher resistivity of about 500 μΩ·cm than other materials.

However, when the lower electrode 12 is formed of TiN and the area of contact of the phase-change layer 13 with the lower electrode 12 is greater than 0.5×0.5 μm², a reset current becomes greater than 10 mA, and thus resulting in very high power consumption.

### SUMMARY OF THE INVENTION

The present invention provides a phase-change memory device that can stably operate with a small reset current.

Also, the present invention provides a method of fabricating the phase-change memory device that can stably operate with a small reset current.

According to an aspect of the present invention, there is provided a phase-change memory device including: a transistor disposed on a semiconductor substrate and including a gate electrode and first and second impurity regions disposed on both sides of the gate electrode; a bit line electrically connected to the first impurity region; and a phase-change resistor electrically connected to the second impurity region. The phase-change resistor includes: a lower electrode formed of a doped SiGe layer; a phase-change layer contacting the lower electrode; and an upper electrode contacting the phase-change layer.

A SiGe layer used to form the lower electrode of the phase-change resistor may be doped with n-type impurities or p-type impurities. More specifically, the SiGe layer may be doped with impurities containing phosphorus(P) ions or boron(B) ions. The SiGe layer may be doped at a dopant concentration of 10¹⁹ to 10²¹/cm³. The resistivity of the doped SiGe layer may range from 3,000 to 8,000 μΩ·cm.

The phase-change layer may be formed of a chalcogen compound containing at least one selected from the group consisting of sulphur(S), selenium(Se), and tellurium(Te). For example, the chalcogen compound may be one selected from the group consisting of InSe, Sb₂Te, SbSe, GeTe, Ge₂Sb₂Te₅(GST), InSbTe, GaSeTe, SnSb₂Te, AginSbTe, (Ge, Sn)SbTe, and GeSb(Se, Te).

Meanwhile, the phase-change memory device may further include a conductive under layer interposed between the semiconductor substrate and the lower electrode. The conductive under layer may be formed of at least one selected from the group consisting of polysilicon, silicide, tungsten, aluminum, and copper.

According to another aspect of the present invention, there is provided a phase-change memory device including: a conductive under layer disposed on a semiconductor substrate; and a phase-change resistor disposed on the conductive under layer. The phase-change resistor includes: a lower electrode formed of a doped SiGe layer; a phase-change layer contacting the lower electrode; and an upper electrode contacting the phase-change layer.

A SiGe layer used to form the lower electrode may be doped with impurities containing P ions or B ions. The SiGe layer may be doped at a dopant concentration of 10¹⁹ to 10²¹/cm³. The resistivity of the doped SiGe layer may range from 3,000 to 8,000 μΩ·cm.

The conductive under layer may be formed of at least one selected from the group consisting of polysilicon, silicide, tungsten, aluminum, and copper.

According to yet another aspect of the present invention, there is provided a method of fabricating a phase-change memory device. The method includes: forming a transistor on a semiconductor substrate, the transistor including a gate electrode and impurity regions disposed on both sides of the gate electrode; and forming a phase-change resistor electrically connected to one of the impurity regions.

The formation of the phase-change resistor may include: forming a lower electrode using a doped SiGe layer; forming a phase-change layer to contact the lower electrode; and forming an upper electrode to be connected to the phase-change layer.

The formation of the lower electrode may include: depositing a SiGe layer; and doping the SiGe layer with P ions or B ions. Alternatively, the formation of the lower electrode may include doping P ions or B ions in-situ during the depositing of a SiGe layer.

P ions or B ions may be doped into the SiGe layer at a dopant concentration of 10¹⁹ to 10²¹/cm³. Also, the SiGe layer may be formed to have a resistivity of 3,000 to 8,000 μΩ·cm.

According to further another aspect of the present invention, there is provided a method of fabricating a phase-change memory device. The method includes: forming a conductive under layer on a semiconductor substrate; and forming a phase-change resistor on the conductive under layer. The formation of the phase-change resistor includes: forming a lower electrode using a doped SiGe layer; forming a phase-change layer to contact the lower electrode; and forming an upper electrode to be connected to the phase-change layer.

The conductive under layer may be formed of at least one selected from the group consisting of polysilicon, silicide, tungsten, aluminum, and copper.

The formation of the lower electrode may include: depositing a SiGe layer; and doping the SiGe layer with P ions or B ions. Alternatively, the formation of the lower electrode may include doping P ions or B ions in-situ during the depositing of a SiGe layer.

P ions or B ions may be doped into the SiGe layer at a dopant concentration of 10¹⁹ to 10²¹/cm³. Also, the SiGe layer may be formed to have a resistivity of 3,000 to 8,000 μΩ·cm.

### BRIEF DESCRIPTION OF THE DRAWINGS

The above and other features and advantages of the present invention will become more apparent by describing in detail exemplary embodiments thereof with reference to the attached drawings in which:

FIG. 1 is a cross-sectional view of a conventional phase-change memory device;

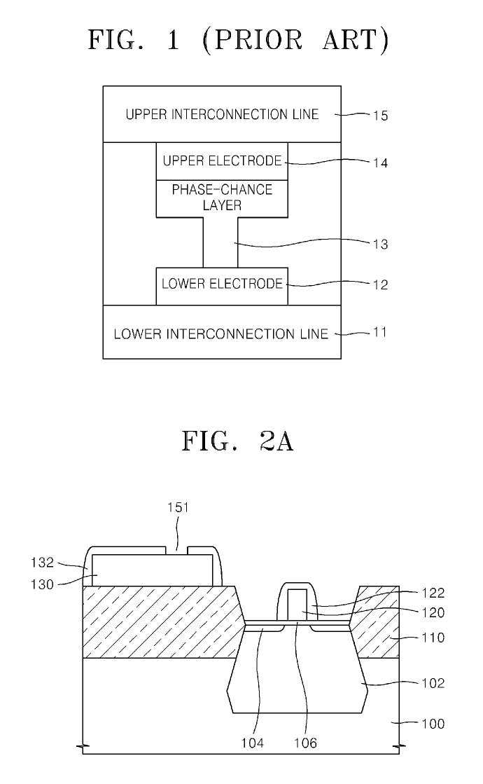

FIGS. 2A through 2D are cross-sectional views illustrating a phase-change memory device and a method of fabricating the same, according to embodiments of the present invention; and

FIG. 3 is a graph showing a comparison of a reset current of a conventional phase-change memory device using a TiN lower electrode and a reset current of a phase-change memory device using a SiGe lower electrode according to the present invention.

### DETAILED DESCRIPTION OF THE INVENTION

The present invention will now be described more fully with reference to the accompanying drawings, in which exemplary embodiments of the invention are shown. It will also be understood that when a layer is referred to as being “on” another layer or substrate, it can be directly on the other layer or substrate, or intervening layers may also be present. In the drawings, the thicknesses of layers and regions are exaggerated for clarity. Like reference numerals in the drawings denote like elements. Although specific terms are employed, they are used in a generic and descriptive sense only and not for purposes of limitation.

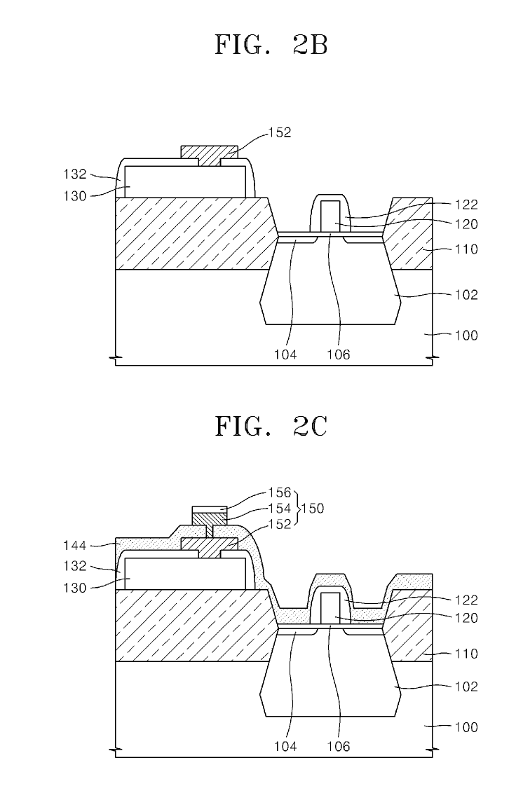

FIGS. 2A through 2D are cross-sectional views illustrating a phase-change memory device and a method of fabricating the same, according to embodiments of the present invention.

Initially, the structure of the phase-change memory device according to an embodiment of the present invention will be described with reference to FIG. 2D.

Referring to FIG. 2D, the phase-change memory device includes a transistor and a phase-change resistor 150. The transistor includes a gate electrode 120 and source and drain 104, which are provided in an active region 102. The phase-change resistor 150 includes a lower electrode 152, a phase-change layer 154, and an upper electrode 156, which are provided on a device isolation region 110. The phase-change memory device further includes a semiconductor substrate 100, a gate oxide layer 106, a gate capping layer 122 and an under capping layer 132, first and second interlayers 144 and 146, and interconnection lines 170. Although the connection between the interconnection lines 170 is not precisely illustrated in FIG. 2D, the phase-change resistor 150 may be electrically connected to the source and drain 104 or the source and drain 104 may be electrically connected to a bit line (not shown) through the interconnection lines 170 connected to an under layer 130, the upper electrode 156, and the source and drain 104. Also, the interconnection lines 170 may be connected to power lines.

In the current embodiment of the present invention, the phase-change resistor 150 is disposed in the device isolation region 110 so that the under layer 130 is adopted to function as a path through which a current is supplied to the phase-change resistor 150. However, the present invention is not limited thereto, and thus, in another embodiment, the phase-change resistor 150 may be disposed on the active region 102 so that the under layer 130 is not required.

In the present embodiment, the lower electrode 152, which generates Joule heat to facilitate a phase change of the phase-change layer 154, may be formed of doped SiGe. When the lower electrode 152 is formed of TiN, which is widely used, its resistivity can be increased to as high as 1,000 μΩ·cm by lowering a deposition temperature or increasing the content of N in a formation material. However, the lower electrode 152, which is formed of doped SiGe, can easily have a high resistivity of about 800 to 50,000 μΩ·cm by controlling the concentration of impurities within the range of 10¹⁹ to 10²¹/cm³, the impurities may be boron(B) ions or phosphorus(P) ions. The above-described concentration range of the impurities can be easily obtained during conventional semiconductor processes. Since Joule heat generated by a resistor is proportional to its resistance, when a lower electrode is formed of a material with a high resistivity, a large amount of Joule heat is generated, thereby facilitating the phase change of a phase-change material and easily causing reset with only a small reset current.

TiN has a thermal conductivity of about 0.19 J/cm·K·s, and SiGe has a thermal conductivity of about 0.085 J/cm·K·s, which is lower than that of TiN. The low thermal conductivity of SiGe is known to be caused by phonon scattering due to lattice defects. Because the loss of Joule heat through interconnection lines can be reduced due to the low thermal conductivity of SiGe, most of the Joule heat can be transmitted to the phase-change material, thereby reducing a reset current.

The phase-change layer 154 may be formed of a material of which the phase is reversibly switched between a crystalline phase and an amorphous phase in response to an electrical input, for example, a current. Such phase-change layer 154 may be formed of chalcogen compounds containing at least one of S, Se, and Te, for example, InSe, Sb₂Te, SbSe, GeTe, Ge₂Sb₂Te₅(GST), InSbTe, GaSeTe, SnSb₂Te, AginSbTe, (Ge, Sn)SbTe, or GeSb(Se, Te).

The upper electrode 156 may be formed of TiN, W, TiW, or TaN. The under layer 130 may be formed of the same material as the gate electrode 120 or a different conductive material from the gate electrode 120 such as Al, or Cu other than polycrystalline silicon (poly-Si). The gate electrode 120 may be formed of a single layer of conductive poly-Si or a double layer of conductive poly-Si and polycide containing metal silicide, such as tungsten silicide. The first and second interlayers 144 and 146 may be formed of a silicon oxide layer, and the gate capping layer 122 and the under capping layer 132 may be formed of an insulating layer, such as a silicon nitride layer, having an etch selectivity with respect to the first and second interlayers 144 and 146. The interconnection lines 170 may be formed of a conductive material such as W, Al, or Cu.

Hereinafter, a method of fabricating the phase-change memory device according to an embodiment of the present invention will be described with reference to FIGS. 2A through 2D.

Referring to FIG. 2A, a well (not shown) is formed in the semiconductor substrate 100 using a photolithography process, an ion implantation process, and a thermal treatment process, and the device isolation region 110 is formed in the semiconductor substrate 100 to define the active region 102. Although FIG. 2A illustrates the device isolation region 110 formed using a local oxidation of silicon (LOCOS) technique, the device isolation region 110 may also be prepared using a shallow trench isolation (STI) technique. Thereafter, the gate oxide layer 106 is formed on the semiconductor substrate 100, and the gate electrode 120 is formed on the gate oxide layer 106. The gate oxide layer 106 may be a thermal oxide layer, and the gate electrode 120 may be formed by depositing a single layer of conductive poly-Si or sequentially stacking a conductive poly-Si layer and a polycide layer containing a metal silicide layer, such as a W silicide layer.

During the formation of the gate electrode 120, the under layer 130, functioning as a path through which a current is supplied to a phase-change resistor, may be formed on the semiconductor substrate 100. The phase-change resistor may be formed on the under layer 130, so that the under layer 130 can function as a path between a transistor, the phase-change resistor and interconnection lines. However, the formation of the under layer 130 is not limited thereto, that is, in another embodiment, the under layer 130 may be formed using a different process not during the formation of the gate electrode 120 using a conductive material, such as poly-Si, Al, or Cu. In another embodiment, the active region 102, defined in the semiconductor substrate 100, may be used as the under layer 130 without additionally having to deposit a thin layer.

During the formation of the gate electrode 120, an upper portion of the gate capping layer 122 may be patterned on the gate electrode 120 such that the upper portion of the gate capping layer 122 is formed of an insulating layer, such as a silicon nitride layer. When the gate electrode 120 and the under layer 130 are formed at the same time, the under capping layer 132 may be further provided on the under layer 130.

Thereafter, a photolithography process and an ion implantation process are performed, thereby forming a lightly doped drain (LDD) region (not shown) in the active region 102 on both sides of the gate electrode 120. A silicon nitride layer is deposited by chemical vapor deposition (CVD) and dry etched, so that a gate spacer that forms a sidewall portion of the gate capping layer 122 is formed on a sidewall of the gate electrode 120. During the formation of the sidewall portion of the gate capping layer 122, an under layer spacer that forms a sidewall portion the under capping layer 132 may be further provided on the under layer 130. After that, a photolithography process and an ion implantation process are performed, thereby forming source and drain regions 104 of an opposite type of conductivity in the active region 102. Thereafter, a photolithography process and a dry etching process are performed, thereby forming a contact hole 151 in the under capping layer 132 to allow the under layer 130 to contact the lower electrode 152 of the phase-change resistor.

Referring to FIG. 2B, a SiGe layer is deposited on the entire surface of the semiconductor substrate 100 having the gate electrode 120 and the under layer 130, to fill the contact hole 151. The SiGe layer is patterned using photolithography and dry etching processes to form the lower electrode 152, which is formed of SiGe. In the present embodiment, the lower electrode 152 fills the contact hole 151 and partially extends over the under capping layer 132. However, the present invention is not limited thereto and, in another embodiment, a chemical mechanical polishing (CMP) process may be performed on the deposited SiGe layer so that the lower electrode 152 may be formed only to fill the contact hole 151 and the top surface of the contact hole 151 is flush with the top surface of the under capping layer 132.

The SiGe layer may be deposited by CVD at a temperature of about 550 to 750° C. under a pressure of about 10 to 100 mTorr using SiH₄, H₄, and GeH₄ reactive gases or SiH₂Cl₂, GeH₄, HCl, and H₂ reactive gases. The SiGe layer is deposited to a thickness of about 10 to 200 nm. In another embodiment, the SiGe layer may be formed by sputtering a Si target and a Ge target in a plasma atmosphere. The SiGe layer may be made polycrystalline, amorphous, or crystalline. The Ge content of the SiGe layer may range from 0 to 100% and may vary with the depth of the SiGe layer.

The resistivity of the SiGe layer may vary in the range of 800 to 50,000 μΩ·cm by controlling the amount of impurities. During the deposition of the SiGe layer, B ions or P ions may be doped into the SiGe layer in-situ by flowing B₂H₆ or PH₃ gas into a reactor. In another embodiment, after depositing the SiGe layer, impurity ions may be doped and diffused into the SiGe layer using a thermal treatment process. In another embodiment, after depositing the SiGe layer, a thermal treatment process may be performed to allow impurity ions to diffuse from the under layer 130 into the SiGe layer.

Referring to FIG. 2C, the first interlayer 144 is deposited on the entire surface of the semiconductor substrate 100 so as to cover the lower electrode 152, and photolithography and dry etching processes are performed, thereby forming a contact hole in the first interlayer 144 to expose the lower electrode 152. The first interlayer 144 may be formed of a silicon oxide layer. Thereafter, a phase-change material and an upper electrode layer are formed on the entire surface of the semiconductor substrate 100 to fill the contact hole, and then, the phase-change material and the upper electrode layer are patterned using photolithography and dry etching processes, thereby forming the phase-change layer 154 and the upper electrode 156. The phase-change layer 154 contacts the lower electrode 152, and the upper electrode 156 is disposed on the phase-change layer 154. The phase-change material may be chalcogen compounds containing S, Se, or Te, for example, InSe, Sb₂Te, SbSe, GeTe, Ge₂Sb₂Te₅(GST), InSbTe, GaSeTe, SnSb₂Te, AgInSbTe, (Ge, Sn)SbTe, or GeSb(Se, Te). The deposition of the phase-change material may be performed using a sputtering process, a CVD process, or an atomic layer deposition (ALD) process. The upper electrode 156 may be formed of TiN, W, TiW, or TaN. The lower electrode 152, the phase-change layer 154, and the upper electrode 156 constitute the phase-change resistor 150.

Referring to FIG. 2D, the second interlayer 146 is formed on the entire surface of the semiconductor substrate 100 having the phase-change resistor 150, and then, photolithography and dry etching processes are performed, thereby forming a contact hole in the second interlayer 146 to connect the under layer 130, the upper electrode 156, the source and drain 104, and the gate electrode 120 to other components, devices, or power lines. Thereafter, a metal layer, for interconnection lines, is formed on the entire surface of the semiconductor substrate 100 to fill the contact hole. The metal layer for the interconnection lines is patterned using photolithography and dry etching processes, thereby forming interconnection lines 170.

Although the current embodiment describes that the under layer 130 is formed at the same time with the gate electrode 120, the under layer 130 may be formed using a different process not during the formation of the gate electrode 120 as described above. In this case, the under layer 130 and the lower electrode 152 may be sequentially deposited and patterned without forming the under capping layer 132.

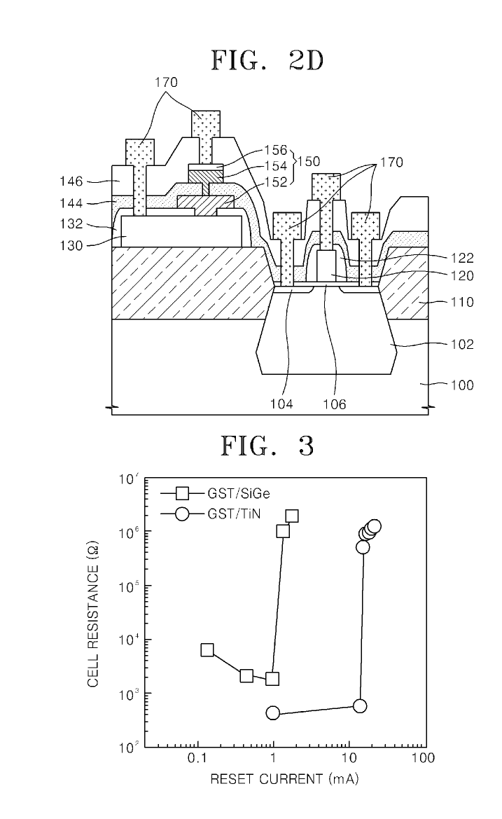

FIG. 3 is a graph showing a comparison of a reset current “∘” of a conventional phase-change memory device using a TiN lower electrode and a reset current [symbol] of a phase-change memory device using a SiGe lower electrode according to the present invention. In both the conventional phase-change memory device and the phase-change memory device according to the present invention, a GST layer was used as a phase-change material layer.

Referring to FIG. 3, it can be confirmed that the reset current [symbol] of the phase-change memory device using the SiGe lower electrode according to the present invention was about 1.4 mA much smaller than the reset current “∘” (about 15 mA) of the conventional phase-change memory device using the TiN lower electrode. As described above, this result is due to a high resistivity and a low thermal conductivity of the doped SiGe lower electrode.

As explained thus far, the phase-change memory device including the SiGe lower electrode according to the present invention has a high resistivity and a low thermal conductivity, so that the phase-change layer can be reset-switched from a low resistance state (i.e., a crystalline phase) to a high resistance state (i.e., an amorphous phase) with only a small reset current. The decreased reset current can lead to the reduced power consumption of the phase-change memory device.

While the present invention has been particularly shown and described with reference to exemplary embodiments thereof, it will be understood by one of ordinary skill in the art that various changes in form and details may be made therein without departing from the spirit and scope of the present invention as defined by the following claims.

What is claimed is:

1. A phase-change memory device comprising:
a transistor disposed on a semiconductor substrate and including a gate electrode and first and second impurity regions disposed on both sides of the gate electrode;
a bit line electrically connected to the first impurity region; and
a phase-change resistor electrically connected to the second impurity region,
wherein the phase-change resistor comprises:
a lower electrode formed of a doped SiGe layer;
a phase-change layer contacting the lower electrode; and
an upper electrode contacting the phase-change layer.

2. The device of claim 1, wherein the doped SiGe layer that forms the lower electrode is doped with n-type impurities or p-type impurities.

3. The device of claim 1, wherein the doped SiGe layer that forms the lower electrode is doped with impurities containing phosphorus(P) ions or boron(B) ions.

4. The device of claim 1, wherein the doped SiGe layer is doped at a dopant concentration of 10¹⁹ to 10²¹/cm³.

5. The device of claim 1, wherein the resistivity of the doped SiGe layer ranges from 3,000 to 8,000 μΩ·cm.

6. The device of claim 1, wherein the phase-change layer is formed of a chalcogen compound containing at least one selected from the group consisting of sulphur(S), selenium(Se), and tellurium(Te).

7. The device of claim 6, wherein the chalcogen compound is one selected from the group consisting of InSe, Sb₂Te, SbSe, GeTe, Ge₂Sb₂Te₅(GST), InSbTe, GaSeTe, SnSb₂Te, AginSbTe, (Ge, Sn)SbTe, and GeSb(Se, Te).

8. The device of claim 1, further comprising a conductive under layer interposed between the semiconductor substrate and the lower electrode.

9. The device of claim 1, wherein the conductive under layer is formed of at least one selected from the group consisting of polysilicon, silicide, tungsten, aluminum, and copper.

10. A phase-change memory device comprising:
a conductive under layer disposed on a semiconductor substrate; and
a phase-change resistor disposed on the conductive under layer,
wherein the phase-change resistor comprises:
a lower electrode formed of a doped SiGe layer;
a phase-change layer contacting the lower electrode; and
an upper electrode contacting the phase-change layer.

11. The device of claim 10, wherein the doped SiGe layer that forms the lower electrode is doped with impurities containing P ions or B ions.

12. The device of claim 10, wherein the doped SiGe layer is doped at a dopant concentration of 10¹⁹ to 10²¹/cm³.

13. The device of claim 10, wherein the resistivity of the doped SiGe layer ranges from 3,000 to 8,000 μΩ·cm.

14. The device of claim 10, wherein the conductive under layer is formed of at least one selected from the group consisting of polysilicon, silicide, tungsten, aluminum, and copper.

15. A method of fabricating a phase-change memory device, the method comprising:
forming a transistor on a semiconductor substrate, the transistor including a gate electrode and impurity regions disposed on both sides of the gate electrode; and
forming a phase-change resistor electrically connected to one of the impurity regions,
wherein the forming of the phase-change resistor comprises:
forming a lower electrode using a doped SiGe layer;
forming a phase-change layer to contact the lower electrode; and
forming an upper electrode to be connected to the phase-change layer.

16. The method of claim 15, wherein the forming of the lower electrode comprises:
depositing a SiGe layer; and
doping the SiGe layer with P ions or B ions.

17. The method of claim 15, wherein the forming of the lower electrode comprises doping P ions or B ions in-situ during the depositing of a SiGe layer.

18. The method of claim 15, wherein P ions or B ions are doped into a SiGe layer at a dopant concentration of 10¹⁹ to 10²¹/cm³.

19. The method of claim 15, wherein the doped SiGe layer is formed to have a resistivity of 3,000 to 8,000 μΩ·cm.

20. A method of fabricating a phase-change memory device, the method comprising:
forming a conductive under layer on a semiconductor substrate; and
forming a phase-change resistor on the conductive under layer,
wherein the forming of the phase-change resistor comprises:
forming a lower electrode using a doped SiGe layer;
forming a phase-change layer to contact the lower electrode; and
forming an upper electrode to be connected to the phase-change layer.

21. The method of claim 20, wherein the conductive under layer is formed of at least one selected from the group consisting of polysilicon, silicide, tungsten, aluminum, and copper.

22. The method of claim 20, wherein the forming of the lower electrode comprises:
depositing a SiGe layer; and
doping the SiGe layer with P ions or B ions.

23. The method of claim 20, wherein the forming of the lower electrode comprises doping P ions or B ions in-situ during the depositing of a SiGe layer.

24. The method of claim 20, wherein P ions or B ions are doped into a SiGe layer at a dopant concentration of 10¹⁹ to 10²¹/cm³.

25. The method of claim 20, wherein the doped SiGe layer is formed to have a resistivity of 3,000 to 8,000 μΩ·cm.
